(19) United States
(12) Patent Application Publication
(10) Pub. No.: US 2025/0048877 A1
(43) Pub. Date: Feb. 6, 2025

(54) TRANSPARENT DISPLAY PANEL

(71) Applicant: TCL CHINA STAR OPTOELECTRONICS TECHNOLOGY CO., LTD., Shenzhen, Guangdong (CN)

(72) Inventor: Xuechao REN, Shenzhen, Guangdong (CN)

(21) Appl. No.: 17/423,018

(22) PCT Filed: May 31, 2021
(86) PCT No.: PCT/CN2021/097474

§ 371 Date: Nov. 1, 2023

(30) Foreign Application Priority Data
Jan. 29, 2021 (CN) 202110125451.8

(51) Int. Cl. H10K 59/50; G02F 1/1514; G02F 1/155; H10K 59/122; H10K 59/80; H10K 102/00; H10K 102/10; H10K 102/20

(52) U.S. Cl. CPC H10K 59/50; G02F 1/1514; G02F 1/155; H10K 59/80517; H10K 59/80523; H10K 59/122; H10K 2102/102; H10K 2102/103; H10K 2102/20; H10K 2102/3026

(57) ABSTRACT

A transparent display panel is provided. The transparent display panel includes a first electrode, a second electrode, and a light-emitting layer disposed between the first electrode and the second electrode. The first electrode is disposed on a light-emitting surface of the light-emitting layer, the second electrode is disposed on one side of the light-emitting layer away from the light-emitting surface, and the second electrode is an electrochromic electrode. The transparent display panel of the present disclosure can reduce an influence of ambient background light on light-emitting pixels without affecting transparent display effect.

### FIELD OF INVENTION

The present disclosure relates to the field of display technologies, and more particularly, to a transparent display panel.

### BACKGROUND OF INVENTION

Compared to liquid crystal displays, organic light-emitting diodes (OLEDs) can realize self-illumination without backlight, thereby being easier to realize transparent display. Each of the OLEDs includes an anode, a hole transport layer, a light-emitting layer, an electron transport layer, and a cathode. A principle of the OLEDs realizing self-illumination is: using ITO transparent glass electrodes and metal electrodes as the anode and the cathode of panels, respectively. Then, driven under a certain voltage, electrons and holes are injected into the electron transport layer and the hole transport layer from the cathode and the anode, respectively, and then transmitted to the light-emitting layer, and the electrons and the holes meet to form excitons to excite light-emitting molecules, which emit visible light after irradiation. The hole transport layer and the electron transport layer can enhance injection and transmission abilities of the electrons and the holes, thereby improving light-emitting performance. Wherein, the holes are hop-transmitted on a highest occupied molecular orbital (HOMO) of organic materials, and the electrons are hop-transmitted on a lowest unoccupied molecular orbital (LUMO) of the organic materials.

There are three main factors that affect transparency of the OLEDs: the anode, the light-emitting layer, and the cathode. It is easy to make the light-emitting layer transparent. Both the anode and the cathode are conductive layers, indium tin oxide (ITO) in the conductive layer of the anode is transparent, while metal electrode materials, such as Ag, Cu, and Mg, in the conductive layer of the cathode are opaque, but the conductive layer of the cathode can also realize translucency when its thickness is below 100 nm. In some application scenarios, when display devices are turned on, ambient background light of transparent display panels will affect light-emitting pixels, especially in scenarios having strong light.

### SUMMARY OF INVENTION

### Technical Problem

Technical problem: a transparent display panel provided by the present disclosure can reduce an influence of the ambient background light on the light-emitting pixels without affecting transparent display effect.

### Technical Solution to the Problem

### Technical Solution

In order to solve the above problems, the present disclosure provides technical solutions as follows.

The present disclosure provides a transparent display panel, which includes a first electrode, a second electrode, and a light-emitting layer disposed between the first electrode and the second electrode. Wherein, the first electrode is disposed on a light-emitting surface of the light-emitting layer, the second electrode is disposed on one side of the light-emitting layer away from the light-emitting surface, and the second electrode is an electrochromic electrode.

In an optional embodiment of the present disclosure, an electrode material of the second electrode includes an electrochromic material.

In an optional embodiment of the present disclosure, the electrochromic material includes at least one of TiO, VO₂, CrO₂, TrO₂, MO₂, V₂O₅, NiO₂, or conductive polyacetylene.

In an optional embodiment of the present disclosure, the electrode material of the second electrode further includes an indium tin oxide material, and the electrochromic material is doped into the indium tin oxide material.

In an optional embodiment of the present disclosure, the electrode material of the second electrode further includes a metal electrode material, and the electrochromic material is doped into the metal electrode material.

In an optional embodiment of the present disclosure, the second electrode includes an electrode layer and an electrochromic layer disposed on one side surface of the electrode layer facing the light-emitting layer.

In an optional embodiment of the present disclosure, a material of the electrochromic layer includes at least one of TiO, VO₂, CrO₂, TrO₂, MO₂, V₂O₅, NiO₂, conductive polyacetylene, or viologen compounds.

In an optional embodiment of the present disclosure, a material of the electrode layer includes an indium tin oxide material.

In an optional embodiment of the present disclosure, a material of the electrode layer includes a metal electrode material.

In an optional embodiment of the present disclosure, the transparent display panel further includes a pixel definition layer, the light-emitting layer is embedded in the pixel definition layer, and the second electrode and the first electrode are disposed on both sides of the pixel definition layer, respectively.

### Beneficial Effect of the Invention

### Beneficial Effect

Beneficial effect: beneficial effects of the present disclosure are that the transparent display panel provided by the present disclosure uses the electrochromic material to manufacture the second electrode disposed on the side of the light-emitting layer away from the light-emitting surface or forms the electrochromic layer on the side surface of the second electrode facing the light-emitting layer. The electrochromic material can have stable and reversible color changes under action of an external electric field. By this characteristic of the electrochromic material, when a pixel unit composed of the first electrode, the second electrode, and the light-emitting layer does not need to be powered on for display, the second electrode is transparent (colorless); and when the pixel unit needs to be powered on for display, the electrochromic material of the second electrode will change from colorless to dark color under action of an electric field. Therefore, the present disclosure can not only reduce an influence of ambient background light on light-emitting pixels and improve a ratio of a light-emitting area to a non-light-emitting area of pixels, but also does not affect transparent display effect.

### BRIEF DESCRIPTION TO DRAWINGS

### Description of Drawings

The accompanying figures to be used in the description of embodiments of the present disclosure or prior art will be described in brief to more clearly illustrate the technical solutions of the embodiments or the prior art. The accompanying figures described below are only part of the embodiments of the present disclosure, from which those skilled in the art can derive further figures without making any inventive efforts.

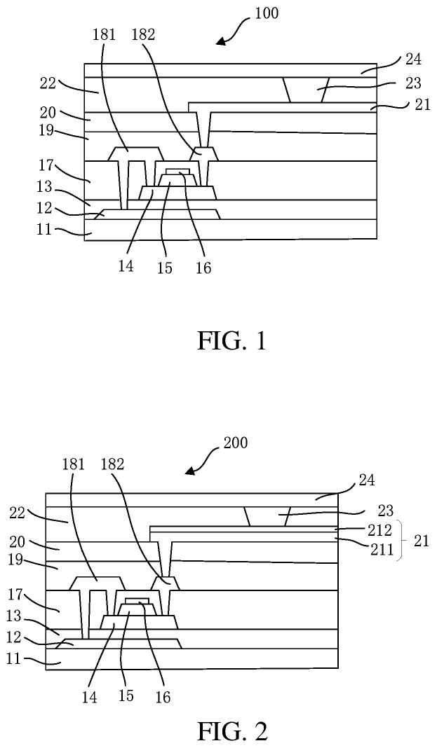

FIG. 1 is a schematic diagram of a transparent display panel according to embodiment 1 of the present disclosure.

FIG. 2 is a schematic diagram of the transparent display panel according to embodiment 2 of the present disclosure.

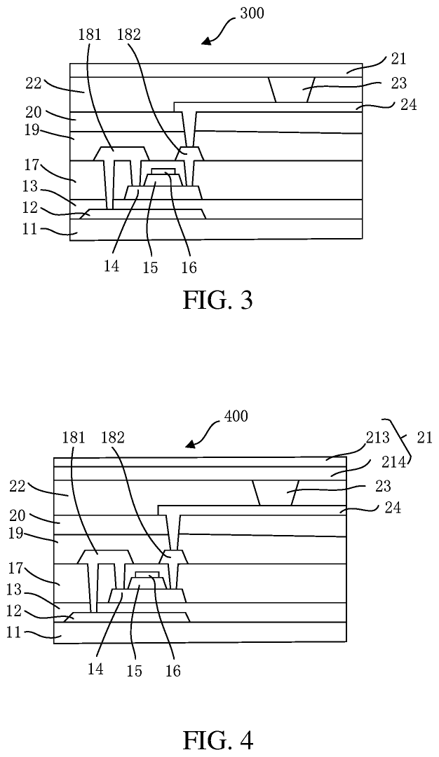

FIG. 3 is a schematic diagram of the transparent display panel according to embodiment 3 of the present disclosure.

FIG. 4 is a schematic diagram of the transparent display panel according to embodiment 4 of the present disclosure.

### INVENTION EMBODIMENTS

### Detailed Description of Preferred Embodiments

The technical solutions in the embodiments of the present disclosure will be clearly and completely described below with reference to the drawings in the embodiments of the present disclosure. Obviously, the described embodiments are only a part of the embodiments of the present disclosure, but not all the embodiments. Based on the embodiments in the present disclosure, all other embodiments obtained by those skilled in the art without creative efforts are within the scope of the present disclosure.

In addition, in the description of the present disclosure, it should be understood that terms such as “on”, “under”, as well as derivative thereof should be construed to refer to the orientation as described or as shown in the drawings under discussion. These relative terms are for convenience of description, do not require that the present disclosure be constructed or operated in a particular orientation, and shall not be construed as causing limitations to the present disclosure. In addition, terms such as “first” and “second” are used herein for purposes of description and are not intended to indicate or imply relative importance or implicitly indicating the number of technical features indicated. Thus, features limited by “first” and “second” are intended to indicate or imply including one or more than one these features. In the description of the present disclosure, “a plurality of” relates to two or more than two, unless otherwise specified.

The present disclosure may repeat reference numerals and/or reference letters in different examples, which are for the purpose of simplicity and clarity, and do not indicate the relationship between the various embodiments and/or arrangements discussed.

Regarding technical problems such as ambient background light of current transparent display panels affecting light-emitting pixels, the present disclosure uses an electrochromic material to manufacture a second electrode disposed on one side of a light-emitting layer away from a light-emitting surface or forms an electrochromic layer on one side surface of the second electrode facing the light-emitting layer. The electrochromic material can have stable and reversible color changes under action of an external electric field. Using this characteristic of the electrochromic material can reduce an influence of the ambient background light on the light-emitting pixels and improve a ratio of a light-emitting area to a non-light-emitting area of pixels, but does not affect transparent display effect of transparent display panels.

A transparent display panel of the present disclosure will be described in detail below in conjunction with specific embodiments.

Referring to FIGS. 1 to 4, the present disclosure provides the transparent display panel, which includes a first electrode 24, a second electrode 21, and a light-emitting layer 23 disposed between the first electrode 24 and the second electrode 21. The first electrode 24 is disposed on the light-emitting surface of the light-emitting layer 23, the second electrode 21 is disposed on the side of the light-emitting layer 23 away from the light-emitting surface, and the second electrode 21 is an electrochromic electrode. The second electrode 21 is transparent when it is not powered on, and the second electrode 21 is changed to dark color when it is powered on.

Referring to FIGS. 1 and 3, in an optional embodiment of the present disclosure, an electrode material of the second electrode 21 includes the electrochromic material.

Referring to FIGS. 2 and 4, in an optional embodiment of the present disclosure, the second electrode 21 includes an electrode layer and the electrochromic layer disposed on the side surface of the electrode layer facing the light-emitting layer 23. The electrochromic layer is transparent when it is not powered on, and the electrochromic layer is changed to dark color when it is powered on.

Specifically, referring to FIG. 1, embodiment 1 of the present disclosure provides the transparent display panel 100, which includes the second electrode 21, the first electrode 24, and the light-emitting layer 23 disposed between the second electrode 21 and the first electrode 24. In an embodiment, the first electrode 24 is a cathode, the second electrode 21 is an anode, a light-emitting mode of the transparent display panel 100 is top emission, and light emitted by the light-emitting layer 23 is emitted from the first electrode 24.

In an optional embodiment of the present disclosure, an electrode material of the first electrode 24 (cathode) is a metal electrode material such as copper, silver, or magnesium, and an electrode material of the second electrode 21 (anode) includes the electrochromic material.

Wherein, the electrochromic material can have stable and reversible color changes under action of an external electric field. Correspondingly, the electrochromic material may be at least one selected from TiO, VO₂, CrO₂, TrO₂, MO₂, V₂O₅, NiO₂, or conductive polyacetylene. Of course, the electrochromic material of the present disclosure is not limited to the above types, and can also be other electrochromic materials that can be used as the electrode material.

In an optional embodiment of the present disclosure, the electrode material of the second electrode 21 (anode) may further include an indium tin oxide material, and the electrochromic material is doped into the indium tin oxide material. Obviously, this anode manufactured by a mixed material using the electrochromic material and the indium tin oxide material has a lower ability to reduce the influence of the ambient background light on the light-emitting pixels than the anode only manufactured by the electrochromic material. Therefore, this anode manufactured by the mixed material using the electrochromic material and the indium tin oxide material is suitable for situations having weaker ambient background light.

In an optional embodiment of the present disclosure, the transparent display panel 100 further includes a hole transport layer and an electron transport layer. The hole transport layer is disposed between the second electrode 21 (anode) and the light-emitting layer 23, and the electron transport layer is disposed between the light-emitting layer 23 and the first electrode 24 (cathode). A light-emitting principle of the transparent display panel 100 is that driven under a certain voltage, electrons and holes are injected into the electron transport layer and the hole transport layer from the first electrode 24 (cathode) and the second electrode 21 (anode), respectively, and then transmitted to the light-emitting layer 23, and the electrons and the holes meet to form excitons to excite light-emitting molecules to irradiate, thereby emitting visible light. The hole transport layer and the electron transport layer can enhance injection and transmission abilities of the electrons and the holes, thereby improving light-emitting performance. Wherein, the holes are hop-transmitted on a highest occupied molecular orbital (HOMO) of organic materials, and the electrons are hop-transmitted on a lowest unoccupied molecular orbital (LUMO) of the organic materials.

In an optional embodiment of the present disclosure, the transparent display panel 100 further includes a pixel definition layer 22, and the second electrode 21 (anode) and the first electrode 24 (cathode) are respectively disposed on two opposite surfaces of the pixel definition layer 22. Specifically, the second electrode 21 (anode) and the light-emitting layer 23 are both embedded in the pixel definition layer 22.

In an optional embodiment of the present disclosure, the transparent display panel 100 also includes a thin film transistor (TFT) array layer, and the TFT array layer includes a transparent substrate 11, a light-shielding layer 12, a buffer layer 13, an active layer 14, a gate insulating layer 15, a gate electrode 16, an interlayer insulating layer 17, a source electrode 181, a drain electrode 182, a passivation layer 19, and a planarization layer 20. The light-shielding layer 12 is disposed on the transparent substrate 11. The buffer layer 13 is disposed on the transparent substrate 11 and covers the light-shielding layer 12. The active layer 14 is disposed on the buffer layer 13. The gate insulating layer 15 is disposed on the active layer 14. The gate electrode 16 is disposed on the gate insulating layer 15. The interlayer insulating layer 17 is disposed on the buffer layer 13 and covers the active layer 14, the gate insulating layer 15, and the gate electrode 16. The source electrode 181 is disposed on the interlayer insulating layer 17 and is electrically connected to the active layer 14 and the light-shielding layer 12, respectively. The drain electrode 182 is disposed on the interlayer insulating layer 17 and is electrically connected to the active layer 14. The passivation layer 19 is disposed on the interlayer insulating layer 17 and covers the source electrode 181 and the drain electrode 182. The planarization layer 20 is disposed on the passivation layer 19. The second electrode 21 (anode) is disposed on the planarization layer 20 and is electrically connected to the drain electrode 182. The pixel definition layer 22 is disposed on the planarization layer 20 and the second electrode 21 (anode).

Wherein, the source electrode 181 is electrically connected to the active layer 14 and the light-shielding layer 12, respectively, by a first through-hole and a second through-hole penetrating through the interlayer insulating layer 17 and the buffer layer 13, and conductive materials filled in the first through-hole and the second through-hole.

Wherein, the drain electrode 182 is electrically connected to the active layer 14 by a third through-hole penetrating through the interlayer insulating layer 17 and the conductive materials filled in the third through-hole.

Wherein, the second electrode 21 (anode) is electrically connected to the drain electrode 182 by a fourth through-hole penetrating through the passivation layer 19 and the planarization layer 20 and the conductive materials filled in the fourth through-hole.

In embodiment 1, the transparent display panel 100 provided by the present disclosure uses the electrochromic material to manufacture the second electrode 21 (anode). The electrochromic material can have stable and reversible color changes under the action of the external electric field. By this characteristic of the electrochromic material, when a pixel unit composed of the anode (the second electrode), the cathode (the first electrode), and the light-emitting layer does not need to be powered on for display, the second electrode is transparent (colorless); and when the pixel unit needs to be powered on for display, the electrochromic material of the second electrode will change from colorless to dark color under action of an electric field. The anode which has its color changing to dark can not only reduce the influence of the ambient background light on the light-emitting pixels and improve the ratio of the light-emitting area to the non-light-emitting area of the pixels, but also does not affect the transparent display effect.

Referring to FIG. 2, embodiment 2 of the present disclosure provides a transparent display panel 200, and a structure of the transparent display panel 200 is similar to a structure of the transparent display panel 100. A difference is that the second electrode 21 includes a first electrode layer 211 and a first electrochromic layer 212 disposed on one side surface of the first electrode layer 211 facing the light-emitting layer 23. A material of the first electrode layer 211 includes the indium tin oxide material. The first electrochromic layer 212 is disposed on the surface of the pixel definition layer 22, and specifically, the first electrochromic layer 212 is embedded in the pixel definition layer 22. The light-emitting layer 23 is disposed between the first electrode 24 (cathode) and the first electrochromic layer 212. The first electrochromic layer 212 is transparent when it is not powered on, and is changed to dark color when it is powered on.

The first electrode layer 211 is electrically connected to the drain electrode 182.

In an optional embodiment of the present disclosure, the first electrochromic layer 212 is deposited on the side surface of the first electrode layer 211 facing the light-emitting layer 23. Specifically, the first electrochromic layer 212 may be deposited on the side surface of the first electrode layer 211 facing the light-emitting layer 23 by physical vapor deposition, evaporation, or spin-coating. In other embodiments, the first electrochromic layer 212 may also be a film layer and is directly attached to the side surface of the first electrode layer 211 facing the light-emitting layer 23. Of course, a method of disposing the first electrochromic layer 212 on the side surface of the first electrode layer 211 facing the light-emitting layer 23 is not limited to deposition and direct bonding.

In an optional embodiment of the present disclosure, a material of the first electrochromic layer 212 includes at least one of TiO, VO₂, CrO₂, TrO₂, MO₂, V₂O₅, NiO₂, conductive polyacetylene, or viologen compounds. Of course, the material of the first electrochromic layer 212 of the present disclosure is not limited to the above types.

In an optional embodiment of the present disclosure, a thickness of the first electrochromic layer 212 ranges from 50 Å to 2000 Å.

The transparent display panel 200 of the present disclosure disposes the first electrochromic layer 212 on the side surface of the first electrode layer 211 facing the light-emitting layer 23, and the first electrode layer 211 and the first electrochromic layer 212 constitute the second electrode 21. The first electrochromic layer 212 can have stable and reversible color changes under the action of the external electric field. By this characteristic of the first electrochromic layer 212, when the pixel unit composed of the second electrode, the first electrode, and the light-emitting layer does not need to be powered on for display, the second electrode is transparent (colorless); and when the pixel unit needs to be powered on for display, the first electrochromic layer 212 will change from colorless to dark color under the action of the electric field. The first electrochromic layer 212 which has its color changing to dark can not only reduce the influence of the ambient background light on the light-emitting pixels and improve the ratio of the light-emitting area to the non-light-emitting area of the pixels, but also does not affect the transparent display effect.

Referring to FIG. 3, embodiment 3 of the present disclosure provides a transparent display panel 300, and a structure of the transparent display panel 300 is similar to the structure of the transparent display panel 100. A difference is that the first electrode 24 is the anode, the second electrode 21 is the cathode, the electrode material of the first electrode 24 is the indium tin oxide material, the electrode material of the second electrode 21 includes the electrochromic material, and an emission method of the transparent display panel 300 is bottom emission. The light emitted by the light-emitting layer 23 is emitted from the first electrode 24 (anode). The first electrode 24 is electrically connected to the drain electrode 182.

In an optional embodiment of the present disclosure, the electrode material of the second electrode 21 (cathode) further includes the metal electrode material, and the electrochromic material is doped into the metal electrode material. The metal electrode material is at least one of silver, copper, or magnesium. Obviously, the second electrode 21 manufactured by a mixed material using the electrochromic material and the metal electrode material has the lower ability to reduce the influence of the ambient background light on the light-emitting pixels than the second electrode 21 only manufactured by the electrochromic material. Therefore, the second electrode 21 manufactured by the mixed material using the electrochromic material and the metal electrode material is suitable for the situations having the weaker ambient background light.

In embodiment 3, the transparent display panel 300 provided by the present disclosure uses the electrochromic material to manufacture the second electrode 21 (cathode). The electrochromic material can have stable and reversible color changes under the action of the external electric field. By this characteristic of the electrochromic material, when the pixel unit composed of the anode, the cathode, and the light-emitting layer does not need to be powered on for display, the second electrode 21 (cathode) is transparent (colorless); and when the pixel unit needs to be powered on for display, the electrochromic material of the second electrode 21 (cathode) will change from colorless to dark color under the action of the electric field. The second electrode 21 (cathode) which has its color changing to dark can not only reduce the influence of the ambient background light on the light-emitting pixels and improve the ratio of the light-emitting area to the non-light-emitting area of the pixels, but also does not affect the transparent display effect.

Referring to FIG. 4, embodiment 4 of the present disclosure provides a transparent display panel 400, and a structure of the transparent display panel 400 is similar to the structure of the transparent display panel 100. A difference is that the second electrode 21 includes a second electrode layer 213 and a second electrochromic layer 214 disposed on one side surface of the second electrode layer 213 facing the light-emitting layer 23. A material of the second electrode layer 213 is the metal electrode material, such as silver, copper, and magnesium. The second electrochromic layer 214 is transparent when it is not powered on, and is changed to the dark color when it is powered on. The light-emitting layer 23 is disposed between the first electrode 24 (anode) and the second electrochromic layer 214. The first electrode 24 is electrically connected to the drain electrode 182.

In an optional embodiment of the present disclosure, the second electrochromic layer 214 is deposited on the side surface of the second electrode layer 213 facing the light-emitting layer 23. Specifically, the second electrochromic layer 214 may be deposited on the side surface of the second electrode layer 213 facing the light-emitting layer 23 by physical vapor deposition, evaporation, or spin-coating. In other embodiments, the second electrochromic layer 214 may also be the film layer and is directly attached to the side surface of the second electrode layer 213 facing the light-emitting layer 23. Of course, a method of disposing the second electrochromic layer 214 on the side surface of the second electrode layer 213 facing the light-emitting layer 23 is not limited to deposition and direct bonding.

In an optional embodiment of the present disclosure, a material of the second electrochromic layer 214 includes at least one of TiO, VO₂, CrO₂, TrO₂, MO₂, V₂O₅, NiO₂, conductive polyacetylene, or viologen compounds. Of course, the material of the second electrochromic layer 214 of the present disclosure is not limited to the above types.

In an optional embodiment of the present disclosure, a thickness of the second electrochromic layer 214 ranges from 50 Å to 2000 Å.

In embodiment 4, the transparent display panel 400 of the present disclosure disposes the second electrochromic layer 214 on the side surface of the second electrode layer 213 facing the light-emitting layer 23, and the second electrode layer 213 and the second electrochromic layer 214 constitute the second electrode 21. The second electrochromic layer 214 can have stable and reversible color changes under the action of the external electric field. By this characteristic of the second electrochromic layer 214, when the pixel unit composed of the anode, the cathode, and the light-emitting layer does not need to be powered on for display, the second electrode 21 is transparent (colorless); and when the pixel unit needs to be powered on for display, the second electrochromic layer 214 will change from colorless to the dark color under the action of the electric field. The second electrochromic layer 214 which has its color changing to dark can not only reduce the influence of the ambient background light on the light-emitting pixels and improve the ratio of the light-emitting area to the non-light-emitting area of the pixels, but also does not affect the transparent display effect.

The present disclosure has been described with a preferred embodiment thereof. The preferred embodiment is not intended to limit the present disclosure, and it is understood that many changes and modifications to the described embodiment can be carried out without departing from the scope and the spirit of the disclosure that is intended to be limited only by the appended claims.

1. A transparent display panel, comprising a first electrode, a second electrode, and a light-emitting layer disposed between the first electrode and the second electrode;
wherein the first electrode is disposed on a light-emitting surface of the light-emitting layer, the second electrode is disposed on one side of the light-emitting layer away from the light-emitting surface, and the second electrode is an electrochromic electrode.

2. The transparent display panel according to claim 1, wherein an electrode material of the second electrode comprises an electrochromic material.

3. The transparent display panel according to claim 2, wherein the electrochromic material comprises at least one of TiO, VO₂, CrO₂, TrO₂, MO₂, V₂O₅, NiO₂, or conductive polyacetylene.

4. The transparent display panel according to claim 2, wherein the electrode material of the second electrode further comprises an indium tin oxide material, and the electrochromic material is doped into the indium tin oxide material.

5. The transparent display panel according to claim 2, wherein the electrode material of the second electrode further comprises a metal electrode material, and the electrochromic material is doped into the metal electrode material.

6. The transparent display panel according to claim 1, wherein the second electrode comprises an electrode layer and an electrochromic layer disposed on one side surface of the electrode layer facing the light-emitting layer.

7. The transparent display panel according to claim 6, wherein a material of the electrochromic layer comprises at least one of TiO, VO₂, CrO₂, TrO₂, MO₂, V₂O₅, NiO₂, conductive polyacetylene, or viologen compounds.

8. The transparent display panel according to claim 6, wherein a material of the electrode layer comprises an indium tin oxide material.

9. The transparent display panel according to claim 6, wherein a material of the electrode layer comprises a metal electrode material.

10. The transparent display panel according to claim 1, further comprising a pixel definition layer, wherein the light-emitting layer is embedded in the pixel definition layer, and the second electrode and the first electrode are disposed on both sides of the pixel definition layer, respectively.

11. The transparent display panel according to claim 2, further comprising a pixel definition layer, wherein the light-emitting layer is embedded in the pixel definition layer, and the second electrode and the first electrode are disposed on both sides of the pixel definition layer, respectively.

12. The transparent display panel according to claim 3, further comprising a pixel definition layer, wherein the light-emitting layer is embedded in the pixel definition layer, and the second electrode and the first electrode are disposed on both sides of the pixel definition layer, respectively.

13. The transparent display panel according to claim 4, further comprising a pixel definition layer, wherein the light-emitting layer is embedded in the pixel definition layer, and the second electrode and the first electrode are disposed on both sides of the pixel definition layer, respectively.

14. The transparent display panel according to claim 5, further comprising a pixel definition layer, wherein the light-emitting layer is embedded in the pixel definition layer, and the second electrode and the first electrode are disposed on both sides of the pixel definition layer, respectively.

15. The transparent display panel according to claim 6, further comprising a pixel definition layer, wherein the light-emitting layer is embedded in the pixel definition layer, and the second electrode and the first electrode are disposed on both sides of the pixel definition layer, respectively.

16. The transparent display panel according to claim 7, further comprising a pixel definition layer, wherein the light-emitting layer is embedded in the pixel definition layer, and the second electrode and the first electrode are disposed on both sides of the pixel definition layer, respectively.

17. The transparent display panel according to claim 8, further comprising a pixel definition layer, wherein the light-emitting layer is embedded in the pixel definition layer, and the second electrode and the first electrode are disposed on both sides of the pixel definition layer, respectively.

18. The transparent display panel according to claim 9, further comprising a pixel definition layer, wherein the light-emitting layer is embedded in the pixel definition layer, and the second electrode and the first electrode are disposed on both sides of the pixel definition layer, respectively.
